(19) United States
(12) Patent Application Publication
(10) Pub. No.: US 2005/0254202 A1
(43) Pub. Date: Nov. 17, 2005

(54) Foldable multimedia display apparatus

(75) Inventor: Tonny Chen, Changhua (TW)

Correspondence Address: BRUCE H. TROXELL, SUITE 1404, 5205 LEESBURG PIKE, FALLS CHURCH, VA, 22041, US

(73) Assignee: E-Lead Electronics Co., Ltd.

(21) Appl. No.: 11/014,182

(22) Filed: Dec. 17, 2004

(30) Foreign Application Priority Data
May 12, 2004 (TW) 093113253

(51) Int. Cl. B65D 73/00; G06F 1/16; H05K 5/00; H05K 7/00

(52) U.S. Cl. 361/681

(57) ABSTRACT

A foldable multimedia display apparatus includes a box which has an opening on a front side, at least one speaker port on the top, a fastening means on the bottom, two sliding tracks on two inner sides to allow a base dock of a display screen to slide forwards and rearwards in the box, and an axle mechanism on the front side of the base dock to turn the display screen upwards and downwards. The apparatus is mounted onto a car dashboard. The display screen is foldable horizontally to be housed in the box when no in use, and extendable outside the box to be turned upright for use.

### BACKGROUND OF THE INVENTION

1. Field of the Invention

The present invention relates to a foldable multimedia display apparatus and particularly to a foldable multimedia display device mountable onto the dashboard of a car that has a display screen foldable horizontally to be housed in a box and extendable from the box to be turned upright for viewing.

2. Description of the Prior Art

A multimedia display device installed in a car has gradually become a popular feature in new cars in recent years. However unless the multimedia display device is equipped on the new car and an original feature built in the car plant, most of the existing cars do not have such a feature. Hence most existing car owners, due to use requirements such as for navigation or provide entertainment for passengers, generally take the approach of installing an external display device 11 (as shown in FIG. 1). The display device 11 is mounted upright onto the dashboard 12. Such a structure has a big disadvantage, namely the display device 11 cannot be folded and stored. It is located on the most visible position in the car, thus easily attracts the attention of burglars. And a burglar can easily break the car window to steal the display device. It could result in a heavy loss to the car owner.

### SUMMARY OF THE INVENTION

In view of the aforesaid disadvantage, the primary object of the present invention is to provide a foldable multimedia display apparatus that is mounted onto the car dashboard and foldable. When the display screen is not in use, it may be folded horizontally and housed in a box. When in use, it may be extended from the box and turned upright.

In order to achieve the foregoing object, the invention mainly includes a box which has an opening on the front side. The top of the box has one or more speaker port to broadcast sound. The bottom of the box has a fastening means. Inside the box, there are two sliding tracks on two inner sides to allow a base dock of a display screen to slide forwards and rearwards. The front side of the base dock has an axle mechanism to allow the display screen to turn upwards or downwards. By means of the construction set forth above, the display screen may be folded horizontally and housed in the box, and extended outside the box and turned upright for viewing.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a schematic view of a conventional external display device.

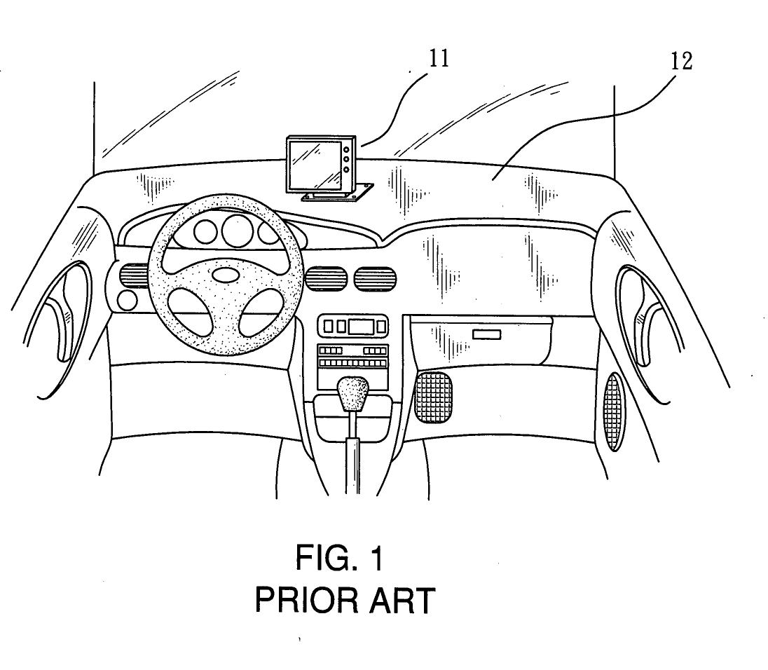

FIG. 2 is a perspective view of the invention.

FIG. 3 is a schematic view of an embodiment of the invention.

FIG. 4 is a schematic view of the internal structure of the invention.

FIG. 5 is a schematic view of the display screen in an operating condition according to the invention.

FIG. 6 is a schematic view of the display screen in another operating condition according to the invention.

FIG. 7 is a schematic view of the display screen in yet another operating condition according to the invention.

FIG. 8 is a schematic view of the axle mechanism of the invention in an operating condition.

FIG. 9 is a perspective view of a second embodiment of the invention.

### DESCRIPTION OF THE PREFERRED EMBODIMENTS

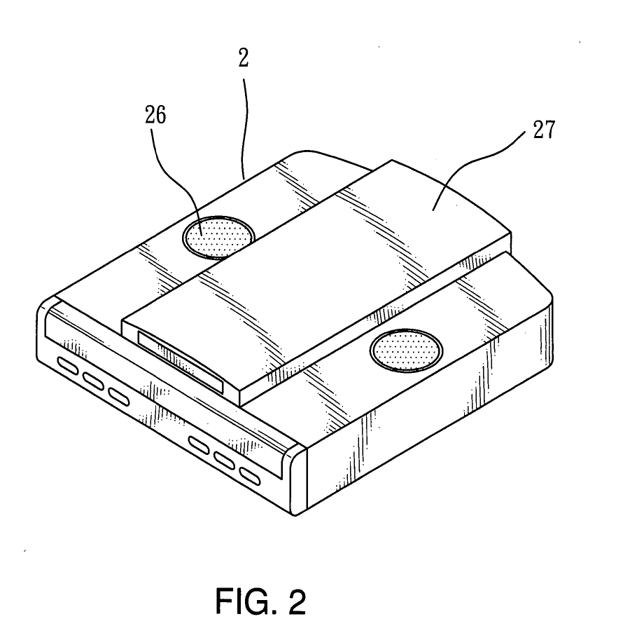

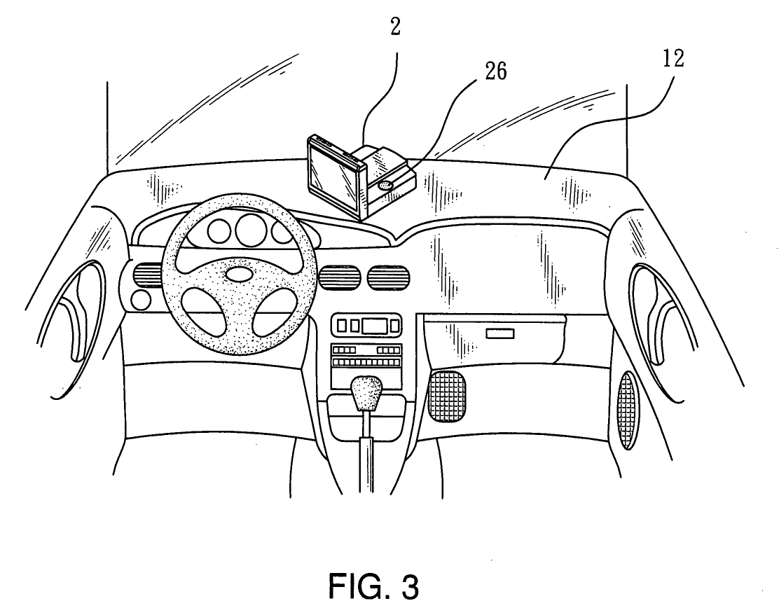

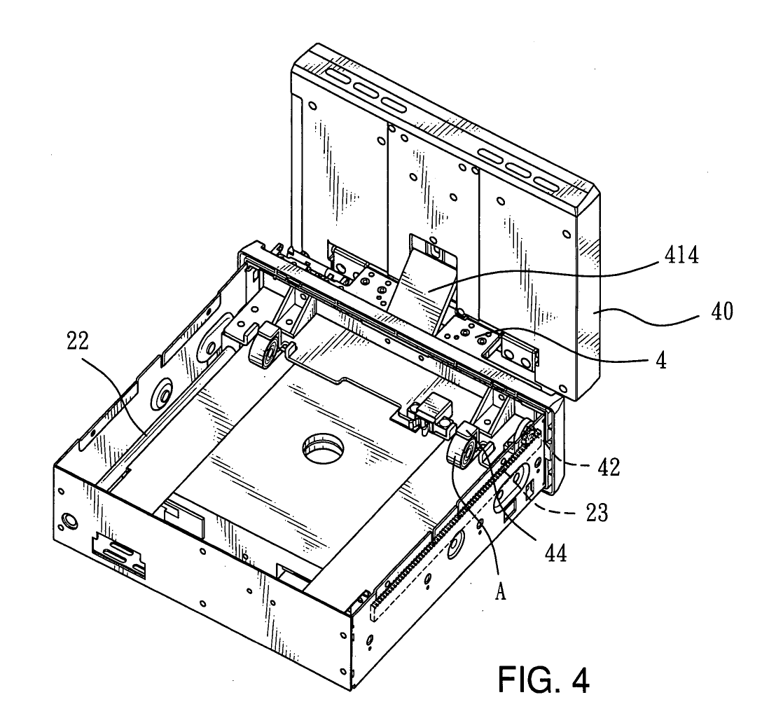

Referring to FIGS. 2 through 5, the invention includes a box 2 which has an opening 21 on a front side, at least one speaker port 26 on the top to broadcast sound and a fastening means 3 on the bottom to install the invention on a car dashboard 12. The box 2 has two sliding tracks 22 on two inner sides to allow a base dock 4 of a display screen 40 to slide forwards and rearwards in the box 2. There is an axle mechanism 41 on the front side of the base dock 4 to turn the display screen 40 upwards and downwards.

The fastening means 3 aims to mount the box 2 onto the dashboard 12. It may be an anchor seat coupling with the box 2 and fastened to the dashboard by screwing. Or a simpler approach may be adopted, such as a double-sided adhesive tape may be used as the fastening means 3 to bond and mount the bottom of the box 2 onto the dashboard 12.

According to the invention, at least one of the sliding tracks 22 in the box 2 has a first gear rack 23 located on one side thereof to engage with a reducing speed buffer gear (or damper) 42 to buffer the forward and rearward sliding speed of the base dock 4.

Between the front side of the box 2 and the rear side of the base dock 4, there is at least one spiral elastic reed A to provide a driving force to move the base dock 4 outside the box 2.

The axle mechanism 41 includes at least one elastic element 411 which provides an elastic force to provide a driving force to turn the display screen 40 upright.

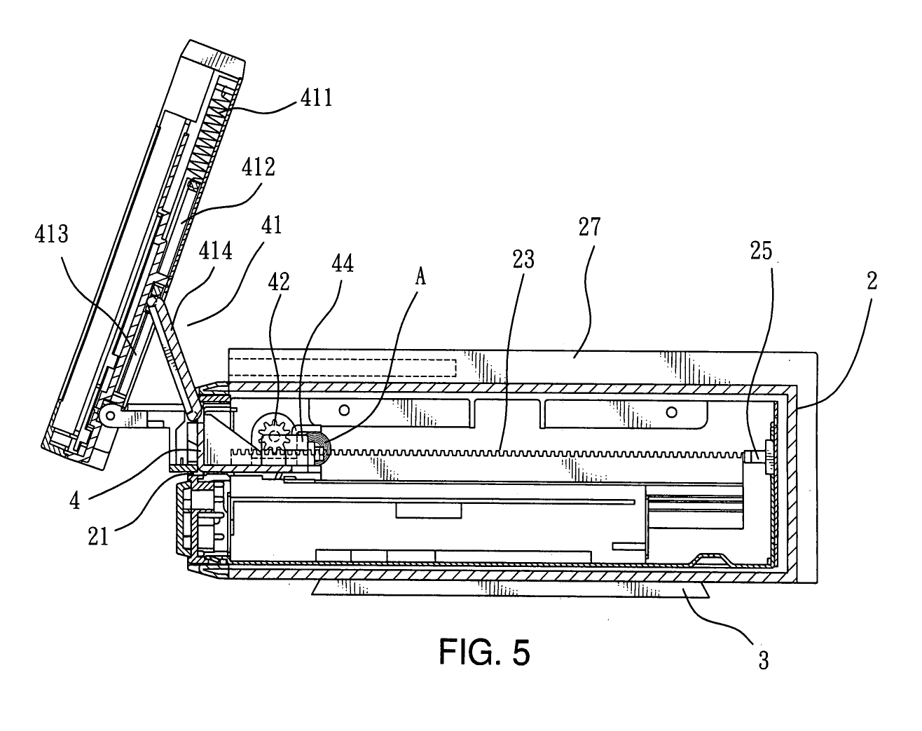

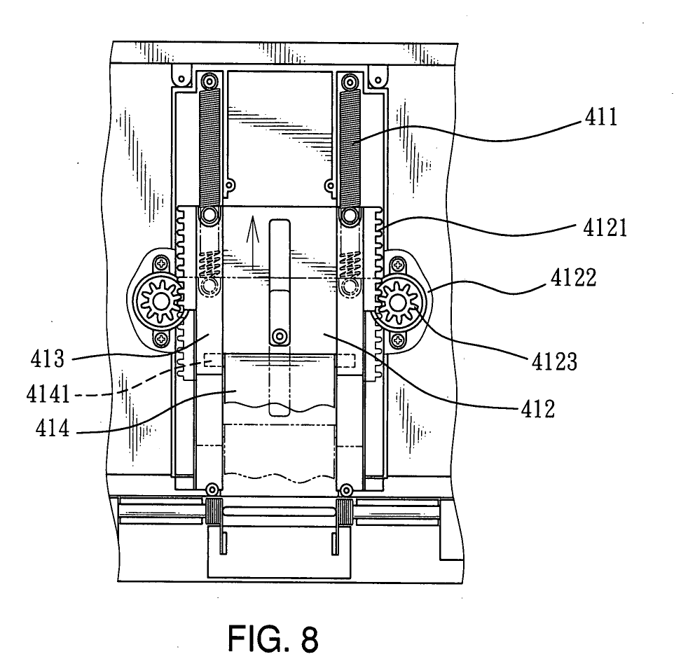

For the axle mechanism 41 to fold the display screen downwards and horizontal or turn upright, it includes at least one elastic element 411, a guiding plate 412, at least one guiding flute 413 and one push plate 414. The elastic element 411 has one end connecting to one end of the guiding plate 412. The guiding plate 412 has other end connecting to the push plate 414. The guiding plate 412 has two sides attaching respectively a second gear rack 4121 to engage with a gear 4123 of a damper 4122 to buffer the speed while the display screen 40 is turning. The push plate 414 has a guiding member 4141 on each of two sides on the upper portion to wedge in the guiding flute 413 to provide a turning path and positioning locations for a upper and a lower anchor spot (referring to FIGS. 5 and 8).

The box 2 further has a recording media reading device 27 to read broadcasting information. The recording media reading device 27 may be an optical disk reader or a flash memory card reader.

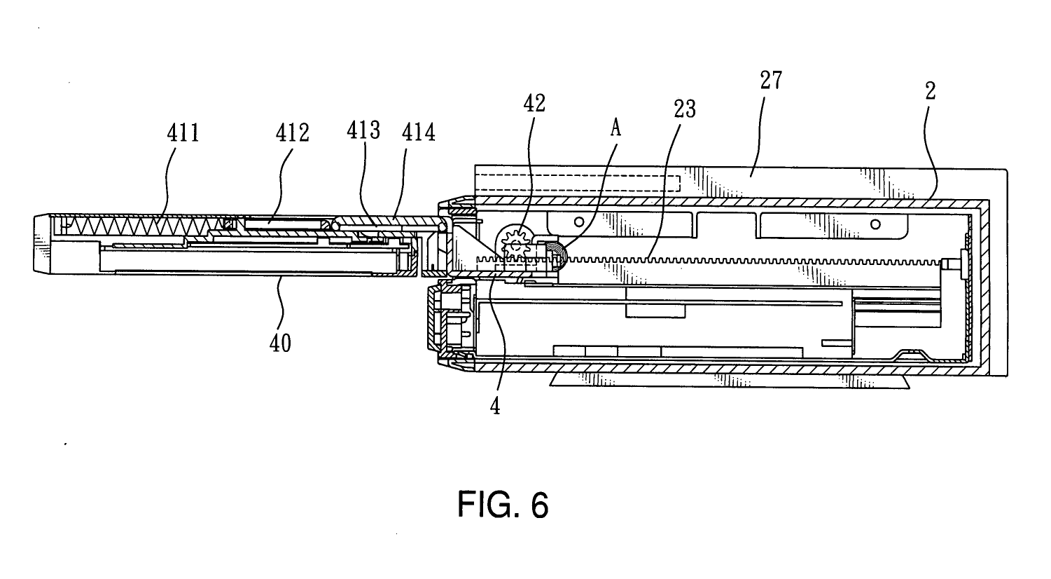

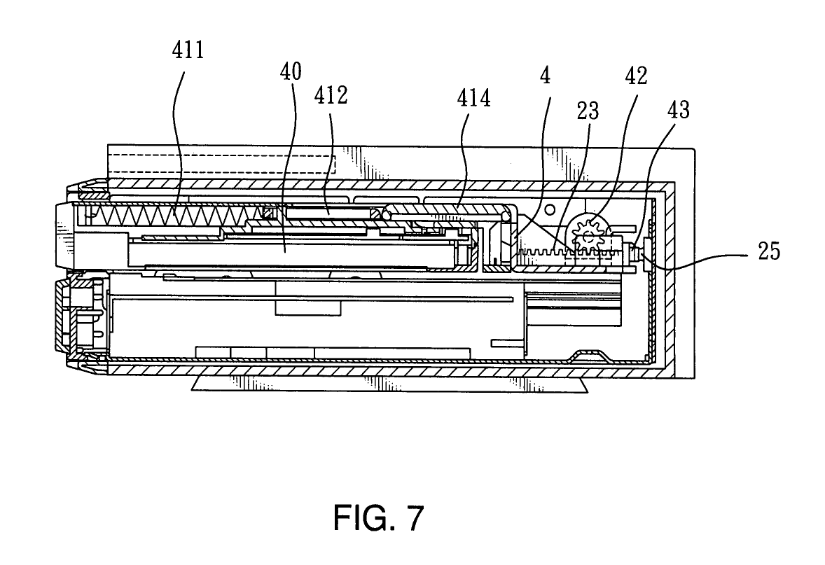

To fold the display screen 40 from the use and upright condition (referring to FIG. 5) to a non-use horizontal position (referring to FIG. 6), move the display screen 40 into the box 2 through the opening 21 until a latch element 43 on a distal end of the base dock 4 reaches a binary switch 25 (which is a standard element) at the rear side of the box 2 to form a latched condition. Then the display screen 40 is fully housed in the box 2 (referring to FIG. 7). During the loading process, the spiral elastic reed A slides inwards with the base dock 4, and is pushed by a ramming member 44 on the base dock 4 and extended. When there is a desire to use the display screen 40, user needs only to push the display screen 40 slightly inwards, the binary switch 25 escapes the latch element 43 (this is the operation principle of the binary switch, namely the first push movement forms a latch condition, and the second push movement forms a release condition. The element and operation principle are known in the art, details are omitted). The base dock 4 is no longer confined, the spiral elastic reed A provides a winding elastic force to drive the base dock 4 to slide outside the box 2 along the sliding tracks 22 until the display screen 40 is extended outside the box 2 and moved away from the horizontal position. Meanwhile, the returning elastic force of the elastic element 411 of the axle mechanism 41 also pulls the guiding plate 412 and the push plate 414 along the guiding flute 413 to push and turn the display screen 40 to a upright position for user viewing (referring to FIG. 5). Moreover, the box 2 may further include a navigation device (not shown in the drawings) to enhance the practicality of the invention.

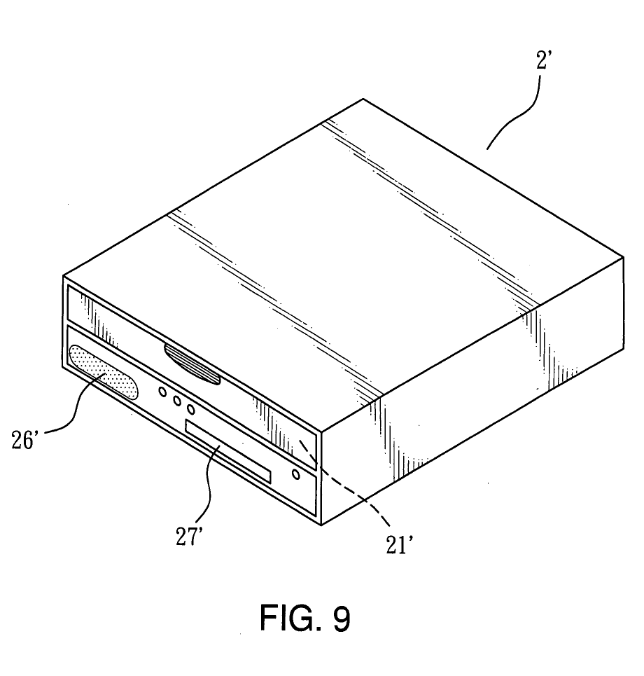

Refer to FIG. 9 for another embodiment of the invention. A box 2′ is provided which has an opening 21′ and one or more speaker port 26′ on the front side to broadcast sound. A recording media reading device 27′ is located on a lower side of the box 2′ to read broadcasting information. The recording media reading device 27′ may be an optical disk reader or a flash memory card reader. The rest portion is constructed same as the one of the previous embodiment, thus details are omitted.

In summary, the invention may be mounted onto the car dashboard as an additional feature not provided in the original car. When the display screen is not in use, it may be folded horizontally and housed in the box. When in use, the display screen may be extended outside the box and turned upright for viewing. A recording media reading device may be included in the box to read broadcasting information and expand the function. A navigation device may also be included in the box to increase the convenience of car driving. Thus the invention offers a great improvement and added value over the conventional techniques.

1. A foldable multimedia display apparatus comprising a box which has an opening on a front side, at least one speaker port on the top, a fastening means on the bottom, two sliding tracks on two inner sides to allow a base dock of a display screen to slide forwards and rearwards in the box, and an axle mechanism on a front side of the base dock to turn the display screen upwards and downwards;
wherein the display screen is foldable horizontally to be housed in the box when no in use, and extendable outside the box to be turned upright for use.

2. The foldable multimedia display apparatus of claim 1, wherein the box further includes a recording media reading device on a upper side to read broadcasting information.

3. The foldable multimedia display apparatus of claim 2, wherein the recording media reading device is an optical disk reader.

4. The foldable multimedia display apparatus of claim 2, wherein the recording media reading device is a flash memory card reader.

5. The foldable multimedia display apparatus of claim 1 further including at least one spiral elastic reed between the front side of the box and a rear side of the base dock to provide a driving force to move the display screen outside the box.

6. The foldable multimedia display apparatus of claim 1, wherein one of the sliding tracks has one side coupled with a gear rack which is engaged with a reducing speed buffer gear.

7. The foldable multimedia display apparatus of claim 1, wherein the axle mechanism includes at least one elastic element to provide a driving force to turn the display screen upright.

8. The foldable multimedia display apparatus of claim 1, wherein the fastening means is a double-sided adhesive tape fastening to the dashboard.

9. The foldable multimedia display apparatus of claim 1, wherein the box contains a navigation device to provide navigation functions.

10. A foldable multimedia display apparatus comprising a box which has an opening and at least one speaker port on a front side, a fastening means on the bottom, two sliding tracks on two inner sides to allow a base dock of a display screen to slide forwards and rearwards in the box, and an axle mechanism on a front side of the base dock to turn the display screen upwards and downwards;
wherein the display screen is foldable horizontally to be housed in the box when no in use, and extendable outside the box to be turned upright for use.

11. The foldable multimedia display apparatus of claim 10, wherein the box further includes a recording media reading device on a lower side to read broadcasting information.

12. The foldable multimedia display apparatus of claim 11, wherein the recording media reading device is an optical disk reader.

13. The foldable multimedia display apparatus of claim 11, wherein the recording media reading device is a flash memory card reader.

14. The foldable multimedia display apparatus of claim 10 further including at least one spiral elastic reed between the front side of the box and a rear side of the base dock to provide a driving force to move the display screen outside the box.

15. The foldable multimedia display apparatus of claim 10, wherein one of the sliding tracks has one side coupled with at least one gear rack which is engaged with a reducing speed buffer gear.

16. The foldable multimedia display apparatus of claim 10, wherein the axle mechanism includes at least one elastic element to provide a driving force to turn the display screen upright.

17. The foldable multimedia display apparatus of claim 10, wherein the fastening means is a double-sided adhesive tape fastening to the dashboard.

18. The foldable multimedia display apparatus of claim 10, wherein the box contains a navigation device to provide navigation functions.
